(19) United States
(12) Patent Application Publication
(10) Pub. No.: US 2026/0213757 A1
(43) Pub. Date: Jul. 23, 2026

(54) METHOD FOR STARTING UP A PHASE-LOCKED LOOP, AND CORRESPONDING INTEGRATED CIRCUIT

(71) Applicant: STMicroelectronics International N.V., Geneva (CH)

(72) Inventors: Pierre MERRIEN, Aix En Provence (FR); Luc GARCIA, Saint Paul de Varces (FR)

(73) Assignee: STMicroelectronics International N.V., Geneva (CH)

(21) Appl. No.: 19/454,670

(22) Filed: Jan. 21, 2026

(30) Foreign Application Priority Data
Jan. 23, 2025 (FR) FR2500714

(51) Int. Cl. H03L 7/099; H03L 7/18

(52) U.S. Cl. CPC H03L 7/099; H03L 7/18

(57) ABSTRACT

In a start-up sequence of a phase-locked loop, the voltage-controlled oscillator is controlled by a first voltage to operate in a linear regime and a first count of a register of a frequency divider is read. Then, the voltage-controlled oscillator is controlled by a second voltage having an offset from the first voltage and a second count of the register is read. A slope of the linear regime is then determined from a difference between the first and second counts and an offset of the first and second voltages. A determination is made of a third voltage needed to reach a target frequency of the output signal as a function of the slope and a deviation between a current value of the register count and a target value corresponding to the target frequency. The voltage-controlled oscillator is then controlled with the third voltage.

### PRIORITY CLAIM

This application claims the priority benefit of French Application for Patent No. FR2500714, filed on Jan. 23, 2025, the content of which is hereby incorporated by reference in its entirety to the maximum extent allowable by law.

### TECHNICAL FIELD

Implementations and embodiments of the invention relate to integrated circuits and, in particular, Phase-Locked Loop (PLL) circuits. More particularly, embodiments herein concern management of the PLL circuit start-up.

### BACKGROUND

Phase-locked loop (PLL) circuits are typically used in digital systems requiring a high internal working frequency, for example in the order of several hundreds of megahertz or one gigahertz.

Phase-locked loop circuits therefore have in particular the role of delivering to these digital systems, for example a programmable core or a microprocessor, an internal clock signal having a high working frequency.

However, the start-up duration (i.e., the time after which the loop is stabilized, with a reference signal and the oscillator output signal close to mutual synchronization) can be very long, for example in some cases between 90 μs (microsecond) and 150 μs or even several hundred microseconds.

Conventional techniques for accelerating start-up have made it possible to lower this duration to about 30 μs, for example using a communication of a setpoint derived from a variation of the frequency generated, to an analog part generating a precharge current controlled by the setpoint and making it possible to modulate frequency by analog means to become closer to the working frequency.

This type of technique, although relatively effective from the speed point of view under nominal conditions, can have difficulties insofar as the operation of the analog part is highly dependent on the technology and possible configurations, and is also very sensitive to variations in Process Voltage Temperature (PVT)—variations (or hazards) in the manufacturing method, possible variations in the supply voltage, and temperature variations—which can negatively impact the effective start-up duration of the loop.

However, a low and stable start-up duration with regard to the operating conditions and other external hazards is generally an important parameter.

There is therefore a need to be able to obtain even faster, stable and reproducible start-up durations of phase-locked loops regardless of any variations in PVT.

### SUMMARY

By indirectly determining the gain of the oscillator in linear mode, and by using the gain determination to quantify distance between the frequency of the signal and a target frequency, and thus control the oscillator with the voltage making it possible to directly reach the target frequency, implementations and embodiments defined below make it possible to meet these needs while benefiting from other advantages. This technique makes it possible to reach the target frequency directly, in a single quantification of the distance (for the vast majority of cases) and in a manner adapted to PVT drifts. In particular, the fast start-up technique of the phase-locked loop is based on minimal analog considerations, but is mostly implemented digitally and thus adapted to any existing technology.

Indeed, according to one aspect, there is provided a method for managing operation of a phase-locked loop, said loop including a voltage-controlled oscillator generating an output signal and a frequency divider keeping count of the pulses of the output signal in a register, the method comprising a start-up sequence including: controlling the oscillator with a first voltage, configured to put the oscillator directly in a linear regime, and reading a first count of the register; controlling the oscillator with a second voltage having an offset with respect to the first voltage and reading a second count of the register; measuring a slope of the linear regime of the oscillator from a difference between the first count and the second count and the offset between the first voltage and the second voltage; controlling the oscillator with a third voltage determined in order to reach a target frequency of the output signal as a function of the slope measured and the deviation between a current value of the register count and a target value corresponding to the target frequency.

Thus, in other words, the effective slope of the oscillator is measured, under effective PVT conditions, in order to determine immediately or almost immediately the final voltage that will allow obtaining a target frequency under these PVT conditions. Determining the final voltage from the measurement of the effective slope is particularly accurate and relevant because the oscillator is intentionally put in the linear regime by the first voltage when measuring the slope.

This mechanism makes it possible to dispense with the time of implementing iterative steps of voltage-frequency pairs to achieve the objective (target voltage-target frequency) and thus benefit from a very fast, reproducible and stable locking time, regardless of method variations or temperature. Furthermore, this mechanism is as independent as possible from analog considerations and makes it possible to facilitate technology portability (i.e., to be easily adaptable to different technologies of phase-locked loops).

According to one implementation, the phase-locked loop includes a phase comparator generating a control signal for the voltage-controlled oscillator, representative of a comparison between the output signal divided by the frequency divider and a reference signal; the start-up sequence being controlled by digital control circuit whose clocking is supplied by a clock signal, the clock signal of the digital control circuit being able to switch between a reference signal and the output signal.

According to one implementation, clocking the control circuit is supplied with the reference signal until the oscillator is controlled with the first voltage, and with the output signal thereafter.

According to one implementation, the phase-locked loop includes a low-pass filter circuit filtering a control signal for the voltage-controlled oscillator; said control of the oscillator with a first voltage being made by a first-precharge circuit by injecting a first-precharge current on a first internal node of the filter and measuring a precharge voltage on a second internal node of the filter, until the first voltage is reached.

For example, the first-precharge circuit communicates to the control circuit that the oscillator is controlled with said first voltage, in order to switch supply of the clocking of the control circuit to the output signal.

According to one implementation, the first internal node of the filter is chosen so as to attenuate the output response of the filter to the injection of the first-precharge current.

According to one implementation, if the current value of the register when the oscillator is controlled with the third voltage differs by more than a tolerance margin (for example 5%) from the target value, a new third voltage is determined as a function of the new deviation between the current value and the target value.

And, for example, if two successive current values of the register when the oscillator is controlled with a third voltage differ by more than the tolerance margin of the target value and are respectively lower and higher than the target value, then the newly determined third voltage becomes closer to an elementary amount of the previous value of the third voltage.

According to another aspect, there is also provided an integrated circuit comprising a phase-locked loop including a voltage-controlled oscillator generating an output signal and a frequency divider keeping count of the pulses of the output signal in a register, and digital control circuit configured to, during a start-up sequence: control the oscillator with a first voltage, configured to put the oscillator directly in a linear regime, and read a first count of the register; control the oscillator with a second voltage having an offset with respect to the first voltage, and read a second count of the register; measure the slope of the linear regime of the oscillator from the difference between the first count and the second count and the offset between the first voltage and the second voltage; and control the oscillator with a third determined voltage in order to reach a target frequency of the output signal as a function of the slope measured and the deviation between a current value of the register count and a target value corresponding to the target frequency.

According to one embodiment, the phase-locked loop includes a phase comparator configured to generate a control signal for the voltage-controlled oscillator, representative of a comparison between the output signal divided by the frequency divider and a reference signal; and the digital control circuit, being clocked by a clock signal, is configured in the start-up sequence, to switch said clock signal between a reference signal and the output signal.

According to one embodiment, the control circuit is configured to switch the clock signal to the reference signal until the oscillator is controlled with the first voltage, and to the output signal thereafter.

According to one embodiment, the phase-locked loop includes a low-pass filter circuit configured to filter a control signal for the voltage-controlled oscillator, and a first-precharge circuit configured to control the oscillator with said first voltage by injecting a first-precharge current on a first internal node of the filter and measuring a precharge voltage on a second internal node of the filter, until the first voltage is reached.

According to one embodiment, the first-precharge circuit is configured to communicate to the control circuit that the oscillator is controlled with said first voltage, the control circuit being configured to switch supply of their clocking to the output signal.

According to one embodiment, the first internal node of the filter is configured to attenuate the output response of the filter to the injection of the first-precharge current.

According to one embodiment, the control circuit is configured to test whether the current value of the register when the oscillator is controlled with the third voltage differs by more than a tolerance margin (for example 5%) from the target value, and if so, to determine a new third voltage as a function of the new deviation between the current value and the target value.

And, for example, the control circuit is configured to monitor whether two successive current values of the register when the oscillator is controlled with a third voltage differ by more than the tolerance margin of the target value and are respectively lower and higher than the target value, and if so, to make the newly determined third voltage become closer to an elementary amount of the previous value of the third voltage.

### BRIEF DESCRIPTION OF THE DRAWINGS

Further advantages and characteristics of the invention will become apparent upon examining the detailed description of non-limiting embodiments and implementations, and from the accompanying drawings, wherein figures:

FIG. 1 is a block diagram of a phase-locked loop (PLL) circuit;

FIG. 2 is a flow diagram for a method for managing the operation, in particular an implementation of an advantageous start-up sequence, of a phase-locked loop;

FIG. 3 schematically illustrates a graph of a transfer function of an oscillator;

FIG. 4 schematically illustrates the implementation of the second step in the graph of the transfer function of the oscillator;

FIG. 5 schematically illustrates the implementation of the third step in the graph of the transfer function of the oscillator;

FIG. 6 is a signal timing diagram according to the start-up sequence of FIGS. 1 to 5; and

FIG. 7 schematically illustrates the filter circuit of the PLL loop.

### DETAILED DESCRIPTION

FIG. 1 is a block diagram of a phase-locked loop (PLL) circuit.

The PLL loop makes it possible to generate an output clock signal having a relatively high output frequency fcvo (in the order of one megaHertz (MHz) or of one gigaHertz (GHz)) at the output, from a reference signal having a relatively low reference frequency fosc (in the order of one kiloHertz (kHz) or of one megaHertz (MHz)).

For the sake of brevity, terms of the type “output signal having an output frequency” may be simplified by the terms “output frequency”, implying that a frequency is carried by an electrical signal within the scope of the present description.

Thus, the PLL loop includes a voltage-controlled oscillator VCO generating the output frequency fvco, as well as an input oscillator OSC, configured to generate the reference frequency fosc, and, to perform frequency multiplication, a feedback loop of the output frequency fvco. In the feedback loop, the output frequency is divided by a frequency divider DIVf, and the divided output frequency fdiv is compared to the reference frequency fosc by a phase comparator PD controlling the voltage-controlled oscillator VCO so as to accelerate or slow down the output frequency if the divided frequency is lower or higher than the reference frequency.

For example, to generate the divided frequency (fdiv=fvco/N), the frequency divider DIVf can typically periodically increment a counter in a register at each pulse (e.g., rising edge) of the output signal fvco. When the counter reaches the value N of the division, a transition is generated in the signal fdiv (rising or falling depending on the previous level of the signal fdiv) whose new level (1 or 0) is maintained until the next transition.

The phase comparator PD is, for example, configured to generate two “down” and “up” signals, of which different binary states, representative of a positive or negative phase difference between the input signal fpd (or fosc/R) and the divided output signal fdiv, make it possible to control downstream of the loop to accelerate or slow down the output fvco generated by the oscillator VCO, for example via a filter FLT.

The filter FLT can, for example, implement low-pass type filtering, and conversion of a current (coming from the phase comparator PD) into voltage, controlling the oscillator VCO.

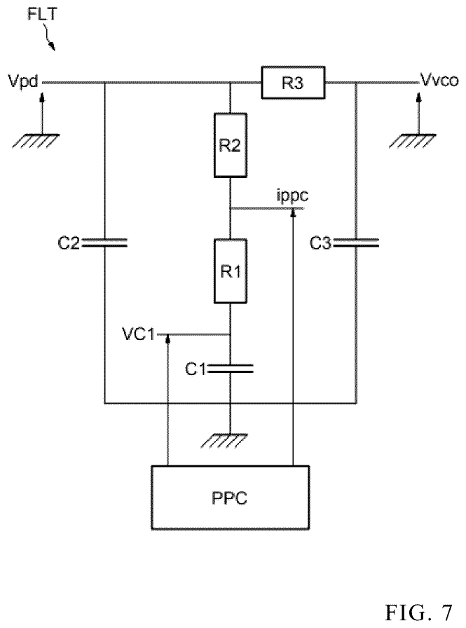

Furthermore, the PLL loop may advantageously include a first-precharge circuit PPC, configured to inject a first-precharge current ippc into the filter FLT and measure a precharge voltage VC1. See below in connection with FIG. 7.

Furthermore, a frequency divider 1/R may optionally be provided to divide the reference frequency fosc and provide the input frequency fpd=fosc/R to the phase comparator PD, in order to achieve frequency multiplication coefficients based on more complex fractions. In the following, it will be considered that the division is made by 1(R=1 ) and that the input frequency fpd of the phase comparator PD is equal to the reference frequency fosc (i.e. fpd=fosc).

The operation of the PLL loop is clocked by control circuit FSM of the state (or finite state) machine type. The state machine FSM is a digital circuit, the clocking of which is supplied by a clock signal ck.

The state machine FSM may advantageously be supplied by the reference frequency fosc as soon as the loop starts up, and at least at the very beginning of the start-up sequence Strt. Then, when an output frequency fvco exists, the state machine FSM may advantageously switch its clock signal in order to be supplied by the output frequency fvco.

For example, the first-precharge circuit PPC is configured to generate a signal for communicating to the state machine FSM that the output signal fvco is generated.

In particular, the mechanism for establishing the first voltage Vctrl1, thus implemented by the first-precharge circuit PPC, can advantageously be used twice, on the one hand in order to generate the first voltage Vctrl1, and on the other hand to communicate to the state machine FSM said signal informing of the presence of the output frequency fvco.

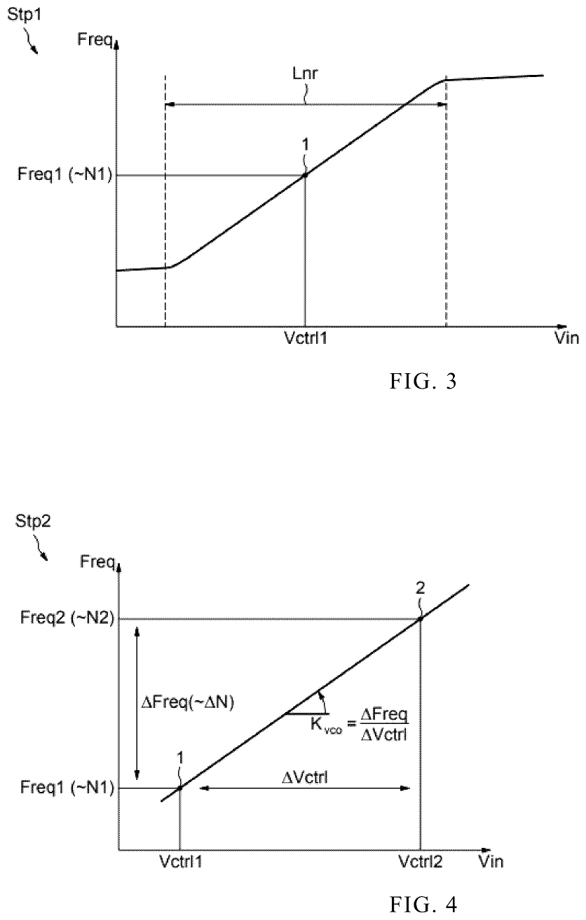

In this regard, see below especially in connection with FIGS. 3 and 7.

This makes it possible to benefit from a clock frequency ck=fvco of the fast state machine FSM, allowing not only to accelerate implementation of the start-up sequence, but also to perform relatively complex operations, such as divisions, without particular time restriction.

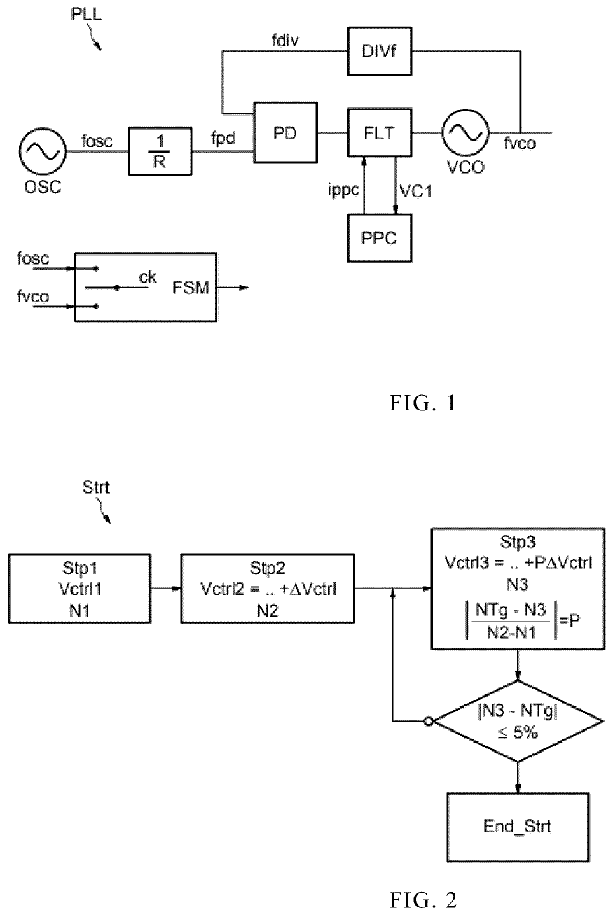

Reference is now made to FIG. 2.

FIG. 2 illustrates an example method for managing the operation of a phase-locked loop, in particular an implementation of an advantageous start-up sequence Strt.

The phase-locked loop PLL especially includes, for example as described previously in connection with FIG. 1, a voltage-controlled oscillator VCO generating an output signal fvco and a frequency divider DIVf for the output signal, keeping count N1, N2, N3 in a register of the pulses of the output signal fvco.

The method Strt includes a first step Stp1, in which the oscillator VCO is controlled with a first voltage Vctrl1, configured to put the oscillator directly in a linear regime, and reading a first count N1 of the register of the frequency divider DIVf.

See also below in connection with FIG. 3.

The method Strt includes a second step Stp2, in which the oscillator VCO is controlled with a second voltage Vctrl2, having an offset+ΔVctrl with respect to the first voltage Vctrl1, and reading a second count N2 of the register.

In the second step Stp2, the slope of the linear regime of the oscillator is measured from the difference ΔN=N2−N1 between the first count N1 and the second count N2 and the offset ΔVctrl between the first voltage Vctrl1 and the second voltage Vctrl2.

See also below in connection with FIG. 4.

The method Strt comprises a third step Stp3, in which the oscillator VCO is controlled with a third voltage Vctrl3, determined in order to reach a target frequency of the output signal, as a function of the slope ΔN/Vctrl1 measured and the deviation between a current value of the count of the register N3 (initially N3=N2) and a target value NTg corresponding to the target frequency.

For example, the tolerance margin can be defined on frequencies greater than +/−5% of the target frequency FreqTg so that if |NTg−N3|≤5% of NTg, then the start-up sequence ends End_Strt, otherwise the third step Stp3 is repeated from the deviation between the current value of the register N3 and the target value NTg.

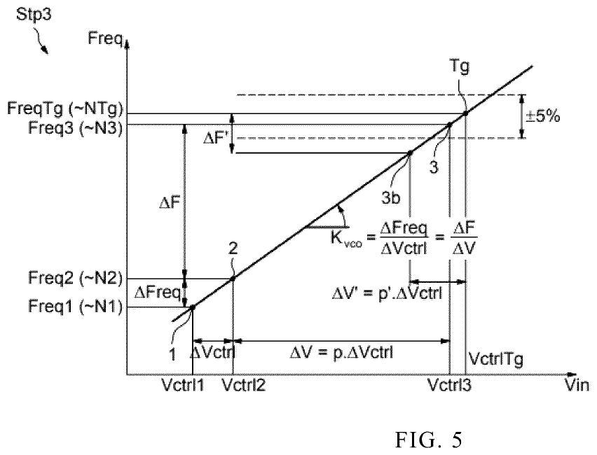

See also below in connection with FIG. 5.

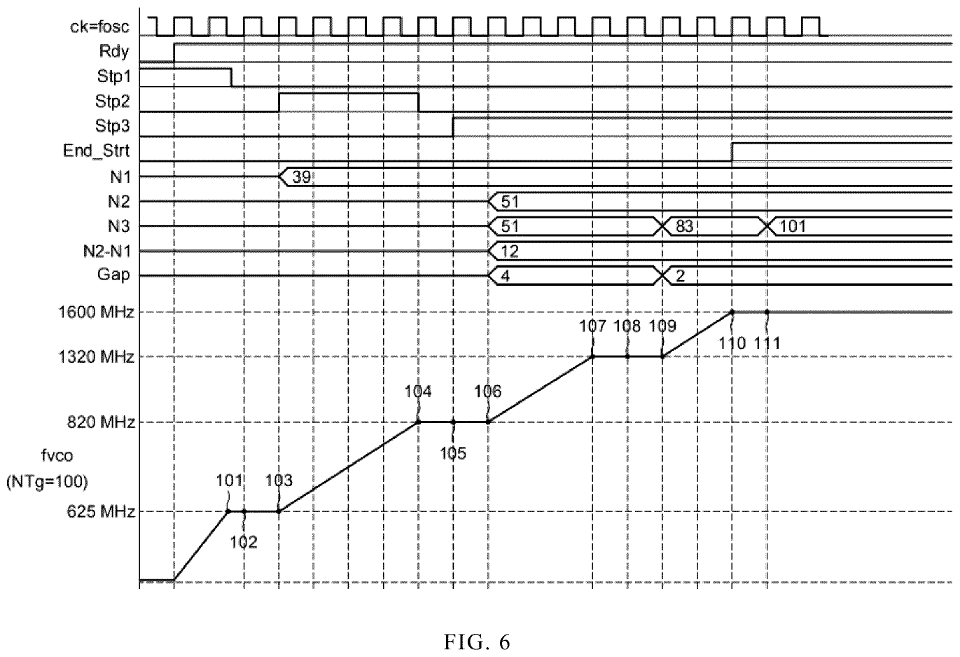

See also below in connection with FIG. 6 for the detailed implementation of an example of the startup sequence Strt.

FIG. 3 schematically illustrates a graph of the transfer function of the oscillator VCO (i.e., the frequency Freq of the output signal fvco as a function of the input voltage Vin that controls it, also called “S-characteristic” due to its stretched “S”-shaped appearance).

The transfer function of the oscillator VCO typically includes a linear region Lnr in which the output frequency fvco is substantially proportional to the input voltage Vin.

Thus, the first step Stp1 of the start-up method comprises controlling the oscillator at a first operating point 1 at a first frequency Freq1 obtained by the first voltage Vctrl1, located in the linear region Lnr.

The first voltage Vctrl1 is, for example, located substantially in the center of the linear region Lnr, and can be determined by a fixed voltage adapted to the circuit, such as 500 mV, advantageously by means of the analog first-precharge circuit PPC (see below in connection with FIG. 7).

Reading the first count N1, which is incremented in the register of the frequency divider DIVf during a cycle (i.e., an entire period) of the reference signal fosc, gives a measurement of the first frequency Freq1, relative to the reference frequency fosc. Alternatively, reading the first count N1 may be made during several cycles of the reference signal fosc, also giving a relative measurement of the output frequency fvco.

For example, reading the first count N1 takes less than 1 μs (microsecond) while controlling the oscillator VCO with the first voltage Vctrl1 takes less than 2 μs.

FIG. 4 schematically illustrates the implementation of the second step Stp2, in the graph of the transfer function of the oscillator VCO.

The second step Stp2 of the start-up method comprises controlling the oscillator at a second operating point 2 at a second frequency Freq2 obtained by the second voltage Vctrl2, again located in the linear region Lnr.

Reading the second count N2, which is incremented in the register of the frequency divider DIVf for at least one cycle of the reference signal fosc, gives a measurement of the second frequency Freq2, relative to the reference frequency fosc.

Thus, in the second step Stp2, the slope Kvco of the linear regime of the oscillator VCO can be measured, said slope being approximated as the ratio ΔFreq/ΔVctrl of the frequency difference ΔFreq over the voltage difference ΔVctrl between the first operating point 1 and the second operating point 2 (where: ΔFreq=Freq2−Freq1; and ΔVctrl=Vctrl2−Vctrl1).

It will be noted that the aforementioned approximation is particularly accurate and reliable because the oscillator is intentionally put in the linear regime during the first step Stp1, and away from inflexions of the “S” characteristic.

The frequency difference ΔFreq is known from the difference ΔN=N2−N1 between the first count N1 and the second count N2.

As for the offset ΔVctrl between the first voltage Vctrl1 and the second voltage Vctrl2, it is known because it is “hard-coded” due to the fact that it comes from the control of the PLL loop.

In this respect, the offset ΔVctrl added is advantageously provided to be large enough to not generate a risk of error in the calculation, and small enough to be considered as an elementary injection (one step) to be reproduced a number of times to become closer to the target frequency.

In other words, in the second step Stp2 an indirect measurement of the effective gain of the oscillator is obtained including the dependence on PVT variations.

FIG. 5 schematically illustrates the implementation of the third step Stp3, in the graph of the transfer function of the oscillator VCO.

The third step Stp3 of the start-up method comprises controlling the oscillator at a third operating point 3 (3b ) at a third frequency Freq3 obtained by a third voltage Vctrl3, again located in the linear region Lnr.

More particularly, the third function Vctrl3 is determined in order to reach, or become closer to, a target frequency FreqTg.

Indeed, knowing the slope Kvco from the first operating point 1 and the second operating point 2 (i.e., Kvco=ΔFreq/ΔVctrl), the value of the third voltage Vctrl3 which positions the frequency Freq3 on the (linear) curve at the target value FreqTg can be obtained.

Indeed, Kvco=ΔFreq/ΔVctrl and Kvco=ΔF/ΔV, with ΔF=FreqTg−Freq2 the difference between the target frequency FreqTg and Ia and the current frequency (i.e., the second frequency Freq2); and ΔV=Vctrl3−Vctrl2 the difference between the third voltage Vctrl3 aimed at obtaining the target frequency and the current voltage (i.e., the second voltage Vctrl2).

Thus, there is ΔV=ΔVctrl*ΔF/ΔFreq.

Again, the frequency difference ΔF is known from the difference ΔN′=NTg−N2 between the second count N2 and the target count NTg (that is the target value NTg of the counter DIVf corresponding to the target frequency FreqTg).

Thus, ΔV=ΔVctrl*ΔN′/ΔN, that is Vctrl3=Vctrl2+ΔVctrl*(NTg−N2)/(N2−N1).

In theory, this calculation makes it possible to directly and precisely reach the target operating point Tg at the target frequency FreqTg by the respective control voltage VctrlTg.

However, due to possible non-linearity of the gain and possible quantification errors in the calculations (the latter being done on integer counts N2, N3, and implementing Euclidean divisions), the result of the calculations of the third voltage Vctrl3 may result in an operating point 3b at a distance greater than a tolerance margin relative to the target operating point Tg. For example, the tolerance margin can be defined on frequencies greater than +/−5% of the target frequency FreqTg.

Thus, it may, for example, be possible to implement a test on the difference between the current value N3 of the register (i.e., the value incremented in the register of the divisor DIVf, over the duration of a cycle of the reference signal fosc) and the target value NTg corresponding to the target frequency FreqTg.

For example, with reference to FIG. 2, it is possible to define as a test: if |NTg−N3|≤0.05*NTg, then the start-up sequence ends End_Strt, otherwise the third step Stp3 is repeated from the operating point 3b (FIG. 5).

In which case the new calculations of Vctrl3′ are implemented from the third operating point 3b, i.e., with ΔF′=FreqTg−Freq3 the difference between the target frequency FreqTg and Ia and the current frequency, i.e., the third frequency Freq3; and ΔV′=Vctrl3′−Vctrl3 the difference between the new third voltage Vctrl3′ aimed at obtaining the target Frequency and the Current Voltage, I.e., the Third Voltage Vctrl3.

Thus, from Kvco=δfreq/δvctrl=δf′/δv′, there is ΔV′=ΔVctrl*ΔF′/ΔFreq.

Again, the frequency difference ΔF′ is known from the difference ΔN′=NTg−N3 between the current value N3 of the count and the target count NTg.

Thus, ΔV′=ΔVctrl*ΔN′/ΔN, i.e. Vctrl3′=Vctrl3+ΔVctrl*(NTg−N3)/(N2−N1).

The third step Stp3 may be repeated in this way, from the last operating point obtained that does not satisfy the stopping condition (that is the test on the tolerance margin for example at 5% of the target frequency), as many times as necessary until the stopping condition is satisfied.

Reference is now made to FIG. 6.

FIG. 6 illustrates the time course of the output frequency fvco according to the start-up sequence Strt, previously described in connection with FIGS. 1 to 5, and more particularly the control signals of the state machine FSM to clock said sequence and the values of the registers used.

In this example, the state machine FSM uses as a clock signal ck the reference frequency fosc, available before starting up the PLL loop, for example as soon as an operational signal Rdy communicated by the reference oscillator OSC is received.

For example, the reference frequency fosc is 16 MHz and the target frequency of the output signal fvco is 1.6 GHz, i.e. NTg=100 (fvco=fosc*NTg).

A first activation signal of the first step Stp1 makes it possible, at the binary level “1”, to control implementation of the first step, i.e., activation of the first-precharge circuit PPC configured to inject a current ippc making it possible to build the first voltage Vctrl1 in the filter FLT of the PLL loop to reach a central part of the linear region of the PLL loop.

When the first voltage Vctrl1 is reached at the instant 101, the output frequency fvco is for example at 625 MHz, and the first activation signal Stp1 is controlled at binary value “0”.

Incrementing the first count N1 may begin during the next cycle of the reference frequency fosc, at the instant 102 and up to the instant 103 at which the first count N1=39 is recorded.

From the instant 103, the second step is implemented by a second activation signal Stp2 brought to binary value “1” by the state machine FSM.

Thus, in the second step, a voltage deviation ΔVctrl is introduced into the control of the oscillator VCO, up to the instant 104 at which the second voltage Vctrl2 is reached and the output frequency fvco is for example at 820 MHz, and at which the second activation signal Stp2 is controlled at binary value “0”.

In this example, it would have taken a number q=4 cycles from instant 103 to instant 104 to introduce the offset ΔVctrl.

Waiting for a cycle, up to the instant 105, makes it possible to ensure stability of the second output frequency fvco, before controlling the third step Stp2 by the third activation signal Stp3 brought to binary value “1” by the state machine FSM.

Incrementing the second count N2 starts at the instant 105 during a cycle until the instant 106 at which the second count N2=51 is recorded.

At the same instant 106, the value of the difference N2−N1=12 is recorded and a value of the third count N3 is initialised at N3=N2=51 for the calculation of the coefficient p.

Still at the same instant 106, the calculation of the coefficient p=NTg/(N2−N1)−N3/(N2−N1), that is p=4 (with NTg=100 in this example) is recorded.

Thus, from the instant 106, the third step introduces the offset ΔV allowing directly reaching the target frequency, as ΔV=p*ΔVctrl, that is in practice a duration of p*q=4*4=16 cycles until the instant 107 at which the third voltage Vctrl3 is reached and the output frequency fvco is, for example, at 1320 MHz.

Waiting for a cycle, up to the instant 108, again makes it possible to ensure stability of the third output frequency fvco.

Incrementation of the third count N3 starts at the instant 108 during a cycle until the instant 109 at which the third count N3=83 is recorded.

At the same instant 109, the calculation of the convergence criterion, for example at 5% of the target count NTg, is carried out on N3, for example by means of hard-coded bit offset operators.

In this example, since |100−83|>5 (5% of NTg=100), the third step Stp3 is repeated.

Thus, in this case, the calculation of the new value of the coefficient p (p′ in FIG. 5) with the current count N3=82 is done, and p=2 is recorded, again at the instant 109.

Thus, from instant 109 to instant 110, the new offset ΔV′ is introduced for p*q=2*4=8 cycles until instant 110 at which the third voltage Vctrl3 is reached and the output frequency fvco is at 1600 MHz.

Waiting for a cycle (not represented) again makes it possible to ensure stability of the third output frequency fvco.

Incrementing the third count N3 during a cycle up to instant 111 records a count N3=101.

At the same instant 111, the calculation of the convergence criterion is validated, since, in this example, |100−101|≤5.

The start-up sequence Strt is completed, and a sequence end signal End_Strt is brought to binary value “1” by the state machine FSM.

It is recalled that, although the method can satisfy the stopping condition (i.e., reach the target within the tolerance margin) as soon as the third step Stp3 is first implemented in the majority of cases, said third step Stp3 may be repeated as many times as necessary, from the last operating points obtained that do not satisfy the stopping condition.

Moreover, in this context of repeating the third step Stp3, the start-up sequence may advantageously comprise detecting oscillations on either side of the target, that is operating points alternately at frequencies lower and higher than the target frequency and outside the tolerance margin. This could, for example, be due to a possible amplification of a (non-zero risk) error, leading to increasing the frequency too much and then decreasing it too much without ever satisfying the stopping condition.

Detecting oscillations comprises in this respect monitoring the last two operating points successively obtained by the method. When switching from an operating point below (respectively above) the target frequency to an operating point above (respectively below) the target frequency without satisfying the stopping condition, then the next elementary current injection q takes place over one cycle less than the previous (i.e., p*(q−1) cycles with p=1). This can be reproduced until resulting in an injection over one cycle.

Reference is now made to FIG. 7.

FIG. 7 schematically illustrates the filter circuit FLT of the PLL loop described previously in connection with FIG. 1.

The filter FLT includes, for example, a Resistive-Capacitive (RC) type connection, arranged to perform low-pass filtering of the signal leaving the phase comparator PD, for example a current on the node Vpd, converted into a control voltage Vvco of the oscillator VCO.

The RC circuit includes a main branch between the input node Vpd and the ground, in which a first resistor R1, a second resistor R2, and a main capacitor C1 are coupled in series.

Furthermore, an input secondary capacitor C2 is coupled between the input node Vpd and the ground, and an output secondary circuit includes a third resistor R3 between the input node Vpd and the output node Vvco as well as an output secondary capacitor C3 between the output node Vvco and the ground.

Moreover, the RC circuit of the filter FLT advantageously includes a first internal node between the first resistor R1 and the second resistor R2, receiving injection of the first-precharge current ippc, as well as a second internal precharge voltage reading node VC1, at the terminals of the main capacitor C1.

The first-precharge circuit PPC is configured to inject the first-precharge current ippc into said injection node ippc of the filter FLT, in order to put the oscillator VCO in a linear regime, in a controlled manner relative to the measurement of the precharge voltage VC1 on said reading node.

The operation of the first-precharge circuit thus includes controlling activation of a current injector when the input is less than 500 mV, for example, and controlling deactivation of the current injector when the input is greater than or equal to 500 mV. The voltage comparison is made by an analog circuit in a way that supports substantially the same PVT variations as the PLL loop.

Injecting the first-precharge current ippc in said injection node, makes it possible, together with balancing the resistive values with respect to the capacitive values, such as R1*C1=R2(C2+C3), to attenuate the response to this current ippc at the output of the filter Vvco (which is amplified).

Consequently, the intensity of the first-precharge current ippc can be increased, for example in the order of 100 μA (which is large compared to conventional uses) without suffering the risk of exceeding the output frequency fvco beyond a safety ceiling.

On the other hand, the measurement of the voltage VC1 at the terminals of the capacitor C1, is faster and more stable than the measurement on the output node Vvco, and furthermore makes it possible to reduce by 80% the drift of the output frequency fvco on the latter Vvco, succinctly, for example, because the primary capacitive value C1 is very large with respect to the secondary capacitive values C2 and C3.

Finally, when the first voltage Vctrl1 is established by the first-precharge circuit PPC, the first-precharge circuit PPC can advantageously be configured to communicate the information to the control circuit that the oscillations of the output signal fvco have started.

1. A method for managing operation of a phase-locked loop which includes a voltage-controlled oscillator generating an output signal and a frequency divider configured to count pulses of the output signal in a register, the method comprising a start-up sequence including:
controlling the voltage-controlled oscillator with a first voltage that puts the voltage-controlled oscillator directly in a linear regime;
then reading a first count of the register;
controlling the voltage-controlled oscillator with a second voltage having an offset with respect to the first voltage;
then reading a second count of the register;
measuring a slope of the linear regime using a difference between the first count and the second count and an offset between the first voltage and the second voltage;
determining a third voltage needed to reach a target frequency of the output signal as a function of the slope and a deviation between a current value of the register count and a target value corresponding to the target frequency; and
controlling the voltage-controlled oscillator with the third voltage.

2. The method according to claim 1, wherein the phase-locked loop includes a phase comparator configured to generate a control signal for the voltage-controlled oscillator, wherein the control signal is representative of a comparison between an output of the frequency divider and a reference signal; and further comprising clocking a digital control circuit which controls the start-up sequence with a clock signal, and switching the clock signal of the digital control circuit between a reference signal and the output signal.

3. The method according to claim 2, wherein clocking of the digital control circuit comprises: supplying the reference signal as the clock signal until the voltage-controlled oscillator is controlled with the first voltage, and thereafter supplying the output signal as a the clock signal.

4. The method according to claim 1, wherein the phase-locked loop includes a low-pass filter circuit filtering a control signal for the voltage-controlled oscillator; wherein controlling the voltage-controlled oscillator with the first voltage comprises:
injecting, by a first-precharge circuit, a first-precharge current on a first internal node of the low-pass filter; and
measuring a precharge voltage on a second internal node of the low-pass filter until the first voltage is reached.

5. The method according to claim 4, further comprising clocking a digital control circuit which controls the start-up sequence with a clock signal; supplying the reference signal as the clock signal until the voltage-controlled oscillator is controlled with the first voltage; thereafter supplying the output signal as the clock signal; and communicating from the first-precharge circuit to the digital control circuit that the voltage-controlled oscillator is controlled with said first voltage in order to switch to supplying the output signal as the clock signal.

6. The method according to claim 4, wherein the first internal node of the low-pass filter is selected so as to attenuate the output response of the low-pass filter to the injection of the first-precharge current.

7. The method according to claim 1, further comprising, when the current value of the register when the voltage-controlled oscillator is controlled with the third voltage differs by more than a tolerance margin from the target value, determining a new third voltage as a function of a new deviation between the current value and the target value.

8. The method according to claim 7, further comprising, when two successive current values of the register with the voltage-controlled oscillator controlled with the third voltage differ by more than the tolerance margin from the target value and are respectively lower and higher than the target value, determining the new third voltage closer to an elementary amount of a previous value of the third voltage.

9. An integrated circuit, comprising:
a phase-locked loop including a voltage-controlled oscillator generating an output signal and a frequency divider configured to count pulses of the output signal in a register; and
a digital control circuit configured, during a start-up sequence, to:
control the voltage-controlled oscillator with a first voltage configured to put the voltage-controlled oscillator directly in a linear regime;
then read a first count of the register;
control the voltage-controlled oscillator with a second voltage having an offset with respect to the first voltage;
then read a second count of the register;
measure a slope of the linear regime using a difference between the first count and the second count and an offset between the first voltage and the second voltage;
determine a third voltage needed to reach a target frequency of the output signal as a function of the slope and a deviation between a current value of the register count and a target value corresponding to the target frequency; and
control the voltage-controlled oscillator with the third voltage.

10. The integrated circuit according to claim 9, wherein the phase-locked loop includes a phase comparator configured to generate a control signal for the voltage-controlled oscillator representative of a comparison between an output of the frequency divider and a reference signal; and wherein the digital control circuit is clocked by a clock signal and configured, in the start-up sequence, to switch said clock signal between a reference signal and the output signal.

11. The integrated circuit according to claim 10, wherein the clock signal for the control circuit is the reference signal until the voltage-controlled oscillator is controlled with the first voltage, and wherein the clock signal for the control circuit is the output signal thereafter.

12. The integrated circuit according to claim 9, wherein the phase-locked loop includes:
a low-pass filter circuit configured to filter a control signal for the voltage-controlled oscillator; and
a first-precharge circuit configured to control the voltage-controlled oscillator with said first voltage by injecting a first-precharge current on a first internal node of the low-pass filter and measuring a precharge voltage on a second internal node of the filter until the first voltage is reached.

13. The integrated circuit according to claim 12, wherein the digital control circuit is clocked by a clock signal, wherein the clock signal for the control circuit is the reference signal until the voltage-controlled oscillator is controlled with the first voltage, and wherein the clock signal for the control circuit is the output signal thereafter, and wherein the first-precharge circuit is configured to communicate to the control circuit that the voltage-controlled oscillator is controlled with said first voltage, the control circuit being configured to switch the clock signal to the output signal.

14. The integrated circuit according to claim 12, wherein the first internal node of the filter is configured to attenuate the output response of the filter to the injection of the first-precharge current.

15. The integrated circuit according to claim 9, wherein the control circuit is configured to identify when the current value of the register with the voltage-controlled oscillator controlled by the third voltage differs by more than a tolerance margin from the target value, and then determine a new third voltage as a function of a new deviation between the current value and the target value.

16. The integrated circuit according to claim 15, wherein the control circuit is configured to monitor whether two successive current values of the register with the voltage-controlled oscillator controlled by the third voltage differ by more than a tolerance margin from the target value and are respectively lower and higher than the target value, and then make a newly determined third voltage closer to an elementary amount of a previous value of the third voltage.
